(19) United States
(12) Patent Application Publication
(10) Pub. No.: US 2026/0339382 A1
(43) Pub. Date: Oct. 29, 2026

(54) APPARATUS AND TECHNIQUES FOR CLOCK SIGNAL GENERATION

(71) Applicant: QUALCOMM Incorporated, San Diego, CA (US)

(72) Inventors: Ibrahim Ramez CHAMAS, Carlsbad, CA (US); Bhushan Shanti ASURI, San Diego, CA (US); Kentaro YAMAMOTO, San Diego, CA (US)

(21) Appl. No.: 19/192,928

(22) Filed: Apr. 29, 2025

(51) Int. Cl. G06F 1/08

(52) U.S. Cl. CPC G06F 1/08

(57) ABSTRACT

Apparatus and techniques for clock generation are provided. An example apparatus generally includes: a first charge pump including a first capacitive element and a second capacitive element, a first terminal of the first capacitive element being coupled to a clock (CLK) node and a first terminal of the second capacitive element being coupled to a complementary clock (CLKB) node; a first inverter including a first transistor and a second transistor with a gate or source coupled to a second terminal of the first capacitive element, drains of the first transistor and the second transistor being coupled to an output of the first inverter; and a second inverter including a third transistor and a fourth transistor with a gate or source coupled to a second terminal of the second capacitive element, drains of the third transistor and the fourth transistor being coupled to an output of the second inverter.

### BACKGROUND

### Field of the Disclosure

Certain aspects of the present disclosure generally relate to electronic components and, more particularly, to clock signal generation circuitry.

### Description of Related Art

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system). Wireless devices may include transmitters for processing signals for transmission via antennas. The wireless device may include various circuit blocks that may operate in the same or different supply voltage domains.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure are directed towards an apparatus for clock generation. The apparatus generally includes: a first charge pump coupled to a first voltage rail and including a first capacitive element and a second capacitive element, a first terminal of the first capacitive element being coupled to a clock (CLK) node and a first terminal of the second capacitive element being coupled to a complementary clock (CLKB) node; a first inverter including a first transistor and a second transistor with a gate or source coupled to a second terminal of the first capacitive element, drains of the first transistor and the second transistor being coupled to an output of the first inverter; and a second inverter including a third transistor and a fourth transistor with a gate or source coupled to a second terminal of the second capacitive element, drains of the third transistor and the fourth transistor being coupled to an output of the second inverter.

Certain aspects of the present disclosure are directed towards a method for clock generation. The method generally includes: receiving, via a first charge pump, a first clock (CLK) signal and a first complementary clock (CLKB) signal, the first CLK signal and the first CLKB signal having a first logic high voltage; generating, via the first charge pump, a second CLK signal and a second CLKB signal based on the first CLK signal and the first CLKB signal, respectively, the second CLK signal and the second CLKB signal having a second logic high voltage greater than the first logic high voltage and a logic low voltage that is greater than zero volts; generating, via a first inverter, a third CLK signal based on the second CLK signal; and generating, via a second inverter, a third CLKB signal based on the second CLKB signal, the third CLK signal and the third CLKB signal comprising the second logic high voltage and a logic low voltage that is zero volts.

Certain aspects of the present disclosure are directed towards an apparatus for clock generation. The apparatus generally includes: a first charge pump coupled to a first voltage rail and including a first capacitive element and a second capacitive element, a first terminal of the first capacitive element being coupled to a clock (CLK) node and a first terminal of the second capacitive element being coupled to a complementary clock (CLKB) node; a first inverter including a first transistor with a gate coupled to the first terminal of the first capacitive element, and a second transistor with a gate coupled to a second terminal of the first capacitive element, drains of the first transistor and the second transistor being coupled to an output of the first inverter; and a second inverter including a third transistor with a gate coupled to the first terminal of the second capacitive element, and a fourth transistor with a gate coupled to a second terminal of the second capacitive element, drains of the third transistor and the fourth transistor being coupled to an output of the second inverter.

Certain aspects of the present disclosure are directed towards an apparatus for clock generation. The apparatus generally includes: a first charge pump coupled to a first voltage rail and including a first capacitive element and a second capacitive element, a first terminal of the first capacitive element being coupled to a clock (CLK) node and a first terminal of the second capacitive element being coupled to a complementary clock (CLKB) node; a first inverter including a first transistor with a source coupled to the first terminal of the first capacitive element and a second transistor with a source coupled to a second terminal of the first capacitive element, drains of the first transistor and the second transistor being coupled to an output of the first inverter; and a second inverter including a third transistor with a source coupled to the first terminal of the second capacitive element and a fourth transistor with a source coupled to a second terminal of the second capacitive element, drains of the third transistor and the fourth transistor being coupled to an output of the second inverter.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example wireless communications network, in which certain aspects of the present disclosure may be practiced.

FIG. 2 is a block diagram of an example access point (AP) and example user terminals, in which certain aspects of the present disclosure may be practiced.

FIG. 3 is a block diagram of an example transceiver front end, in which certain aspects of the present disclosure may be practiced.

FIG. 4 is a block diagram of circuitry including a clock generation circuit to convert a clock signal from one voltage domain to another voltage domain, in accordance with certain aspects of the present disclosure.

FIG. 5 illustrates a clock generation circuit using two supply voltages, in accordance with certain aspects of the present disclosure.

FIG. 6 is a block diagram of circuitry including a clock generation circuit using a single supply voltage to interface different clock domains, in accordance with certain aspects of the present disclosure.

FIG. 7 illustrates a clock generation circuit using a single supply voltage to interface different clock domains, in accordance with certain aspects of the present disclosure.

FIG. 8 illustrates an example sequential clock generation circuit, in accordance with certain aspects of the present disclosure.

FIG. 9 is a flow diagram illustrating example operations for clock generation, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed toward clock generation circuitry that may be used as an interface between different voltage domains. For example, a clock signal for a first voltage domain may have a certain logic high voltage, and a clock signal for a second voltage domain may have a higher logic high voltage. The clock generation circuitry described herein may generate the clock signal for the second voltage domain based on the clock signal for the first voltage domain. In some aspects, the clock generation circuitry may use a single voltage rail to generate the clock signal, as described in more detail herein. The clock generation circuitry may include a charge pump to generate a clock signal with a higher logic high voltage and a higher logic low voltage (e.g., a logic low voltage greater than zero volts) compared to the clock signal for the first voltage domain. An inverter may then be used to generate the clock signal for the second voltage domain with the higher logic high voltage and a logic low voltage equal to zero volts. In other words, the inverter may receive the voltage level-shifted clock signal from the charge pump and reference the voltage level-shifted clock signal to electric ground (e.g., zero volts). The clock generation circuitry allows different circuits of an electronic device to operate using different supply voltages, increasing power efficiency.

### Example Wireless Communications

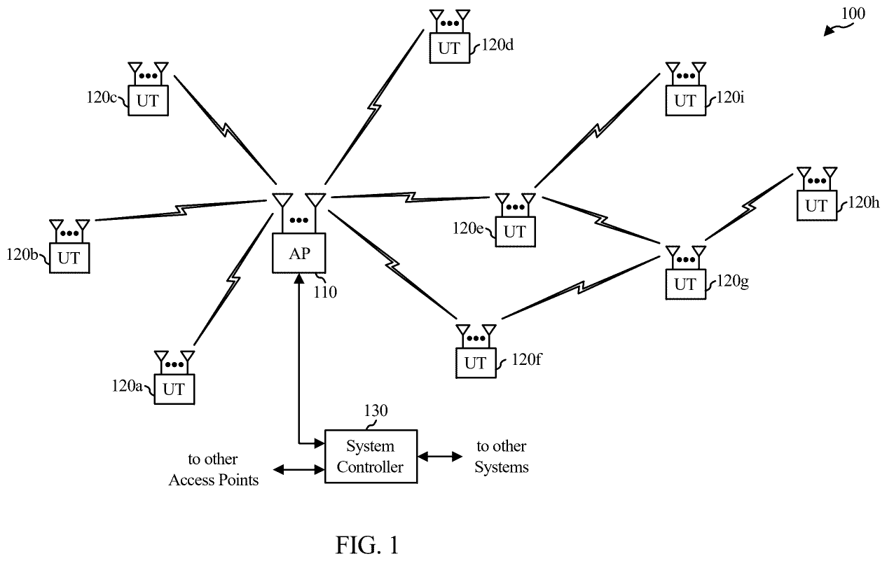

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), a next generation Node B (gNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported).

In some aspects, the user terminal 120 or access point 110 may include a clock generation circuit configured to generate a clock signal for one supply voltage domain based on a clock signal for another supply voltage domain, as described in more detail herein.

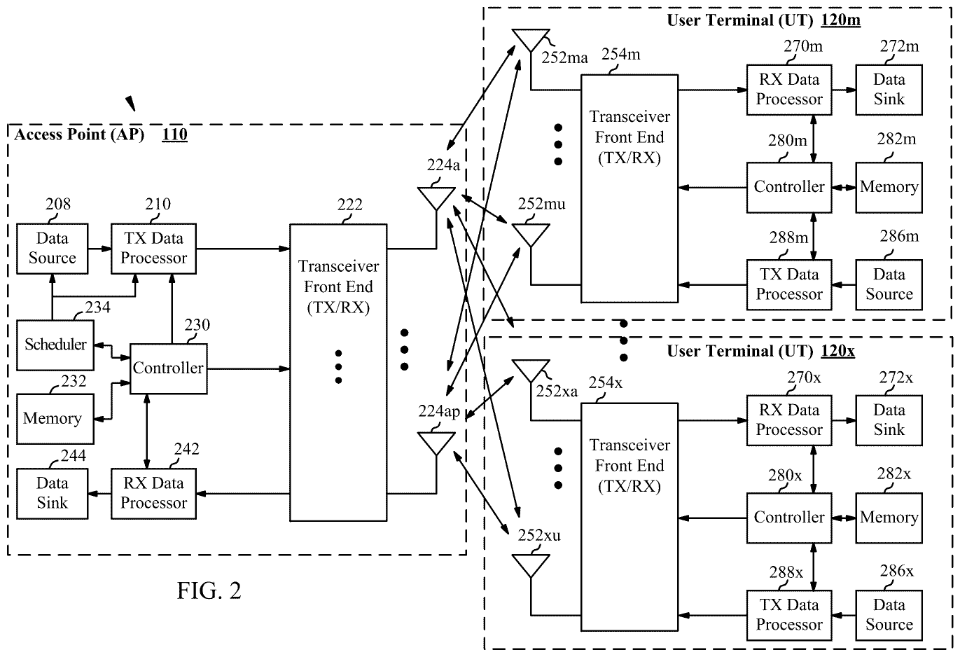

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a transmitter (TX) data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ}for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. A receiver (RX) data processor 242 processes (e.g., demodulates, deinterleaves, and decodes) the recovered uplink data symbol stream in accordance with the rate used for that stream to obtain decoded data. The decoded data for each user terminal may be provided to a data sink 244 (e.g., corresponding to data sink 272 of UT) for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

In some aspects, the user terminal 120 or access point 110 may include a clock generation circuit configured to generate a clock signal for one supply voltage domain based on a clock signal for another supply voltage domain, as described in more detail herein. The clock signals may be used by circuit blocks that may be part of the transceiver front end 254 or 222 or any other electronic components.

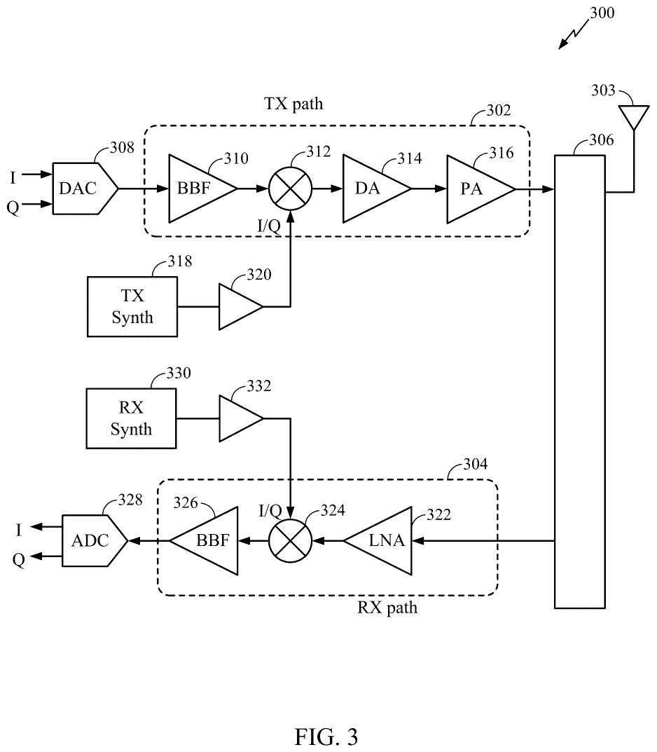

FIG. 3 is a block diagram of an example transceiver front end 300, such as transceiver front ends 222, 254 in FIG. 2, in which aspects of the present disclosure may be practiced. The transceiver front end 300 includes at least one transmit (TX) path 302 (also known as a transmit chain) for transmitting signals via one or more antennas and at least one receive (RX) path 304 (also known as a receive chain) for receiving signals via the one or more antennas. When the TX path 302 and the RX path 304 share an antenna 303, the paths may be connected with the antenna via an interface 306, which may include any of various suitable radio frequency (RF) devices, such as a switch, a duplexer, a diplexer, a multiplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, the DA 314, and the PA 316 may be included in a radio frequency integrated circuit (RFIC). In some cases, the PA 316 may be external to the RFIC. In some cases, the DA 314 may include a pre-DA that may drive a DA, where the DA drives the PA 316.

The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency-conversion process produces the sum and difference frequencies of the LO frequency and the frequencies of the baseband signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303. While one mixer 312 is illustrated, several mixers may be used to upconvert the filtered baseband signals to one or more intermediate frequencies and to thereafter upconvert the intermediate frequency (IF) signals to a frequency for transmission.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (e.g., downconvert). The baseband signals output by the mixer 324 may be filtered by the BBF 326 before being converted by an analog-to-digital converter (ADC) 328 to digital I and/or Q signals for digital signal processing.

Certain transceivers may employ a variable-frequency oscillator (e.g., a voltage-controlled oscillator (VCO) or a digitally controlled oscillator (DCO)) to generate a stable, tunable LO signal with a particular tuning range. Thus, the transmit LO signal may be produced by a TX frequency synthesizer 318, which may be buffered or amplified by amplifier 320 before being mixed with the baseband signals in the mixer 312. Similarly, the receive LO signal may be produced by an RX frequency synthesizer 330, which may be buffered or amplified by amplifier 332 before being mixed with the RF signals in the mixer 324. For certain aspects, a single frequency synthesizer may be used for both the TX path 302 and the RX path 304.

In certain aspects, the user terminal 120 or access point 110 may include a clock generation circuit configured to generate a clock signal for one supply voltage domain based on a clock signal for another supply voltage domain, as described in more detail herein. One or more components of the transceiver front end 300 may operate using the clock signals. For example, the generated clock signal may be used to drive transistors of the mixer 312 or mixer 324.

While FIGS. 1-3 provide wireless communications as an example application in which certain aspects of the present disclosure may be implemented to facilitate understanding, certain aspects described herein may be used in any of various other suitable systems.

### Example Techniques for Clock Signal Generation

Certain aspects of the present disclosure are directed towards charge pump (CP) circuitry that may be used to scale (voltage level-shift) a clock signal (e.g., a clock signal for radio frequency (RF) circuitry) by a certain voltage, allowing different voltage domains to be used for different circuit blocks. In some aspects, the CP circuitry may have a symmetric architecture to generate a dual-polarity clock signal that may be used to drive n-type metal-oxide-semiconductor (NMOS) and p-type metal-oxide-semiconductor (PMOS) transistors. An inverter stage (e.g., a stacked high-speed inverter stage) may be used to convert a level-shifted clock signal generated by the CP circuitry that transitions between logic low and logic high voltages that are both greater than zero to a clock signal that transitions to zero volts when logic low.

In some implementations, different circuit blocks of an electronic device may be powered using different supply voltage. There may be a direct trade-off between the performance (e.g., in terms of phase noise, slew rate, or power dissipation) of a circuit and the associated supply voltage level for the circuit. Different supply voltages may be used for different circuit blocks to increase performance (e.g., reduce power consumption). For example, one circuit block may use a lower supply voltage than another circuit block to increase overall performance. Some aspects of the present disclosure are directed towards converting a clock signal from a first to a second voltage domain, facilitating operations using different supply voltages for different circuit blocks.

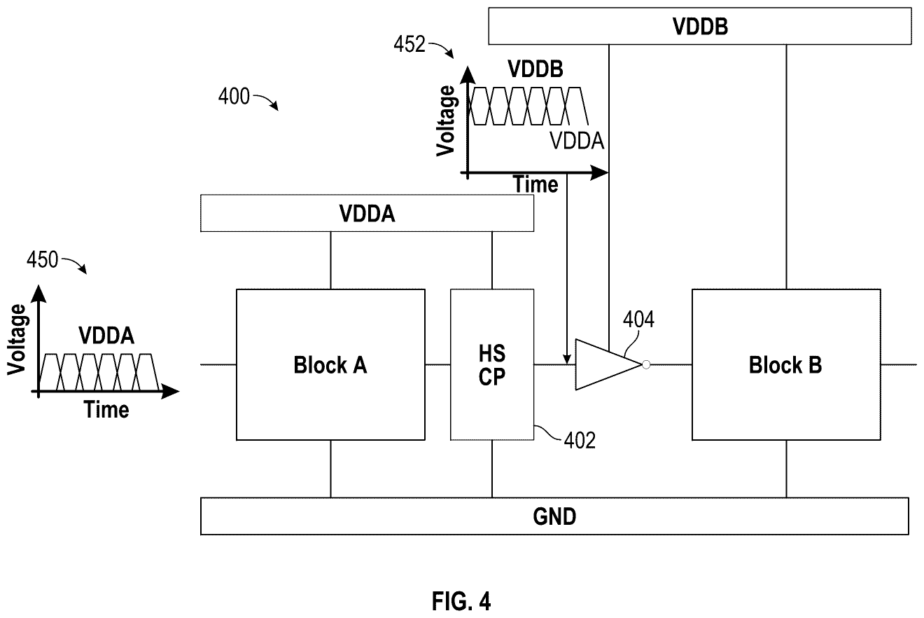

FIG. 4 is a block diagram of circuitry, including a clock generation circuit 400 to convert a clock signal from one voltage domain to another, in accordance with certain aspects of the present disclosure. As shown, circuit block A may be powered with a supply voltage VDDA, and circuit block B may be powered with a supply voltage VDDB, where VDDB is greater than VDDA. VDDB may be two times VDDA, for example. Circuit block A may receive a clock signal, as shown in graph 450, that is in the VDDA domain (e.g., transitions between zero volts (at a reference potential node for the circuitry, labeled “GND”) and VDDA). A high-speed (HS) CP 402 may be used to shift the voltage level of the clock signal in the VDDA domain to generate a clock signal in the VDDB domain. As shown in graph 452, the clock signal at the output of the CP 402 may transition between VDDA and VDDB. The clock signal at the output of the CP 402 may be provided to inverter circuitry 404 (e.g., stacked-core supply referenced inverter) to generate a clock signal in the VDDB domain that transitions between zero volts and VDDB, which may be provided to operate circuit block B. In some aspects, clock signals of different polarities may be generated to drive NMOS and PMOS transistors of circuit block B, such as NMOS and PMOS transistors of a mixer (e.g., mixer 312 or mixer 324 of FIG. 3).

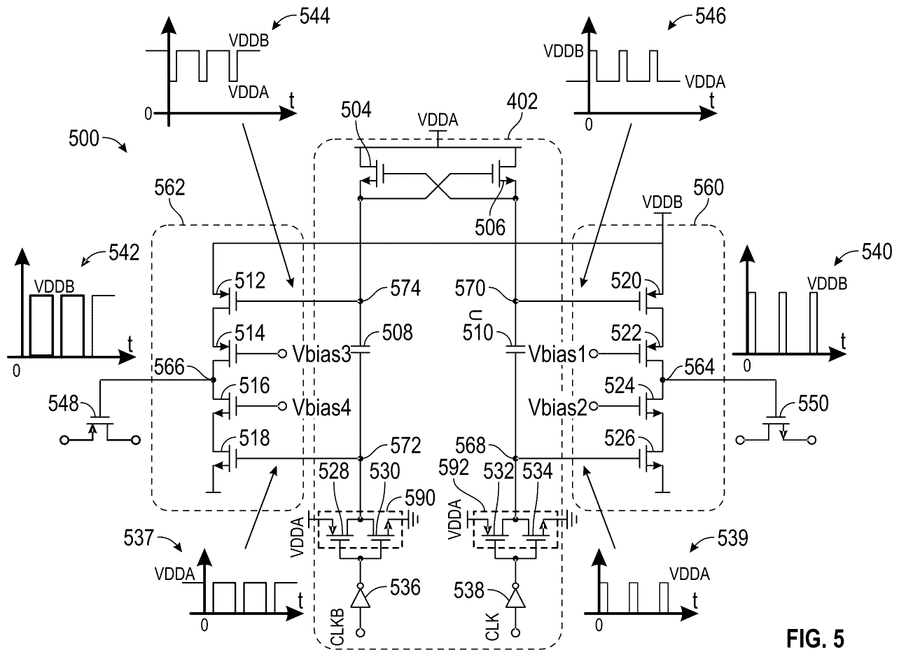

FIG. 5 illustrates a clock generation circuit 500 using two supply voltages, in accordance with certain aspects of the present disclosure. As shown, the clock generation circuit 500 may receive a supply voltage VDDA at a VDDA rail and a supply voltage VDDB at a VDDB rail. VDDB may be twice VDDA, in some cases. The clock generation circuit 500 may include the symmetric CP 402 that receives a clock (CLK) signal (e.g., at a CLK node) and a complementary clock (CLKB) signal (e.g., at a CLKB node) at inputs of respective inverters 538, 536. The CLK and CLKB signals may be in the VDDA domain (e.g., transition between zero volts and VDDA).

The output of inverter 536 may be coupled to an input of another inverter 590 including transistors 528, 530. The gates of transistors 528, 530 may be coupled to an output of inverter 536, and drains of transistors 528, 530 may be coupled to a first terminal of a capacitive element 508 coupled to node 572. As shown, the source of transistor 528 is coupled to the VDDA rail, and the source of transistor 530 is coupled to a reference potential node (e.g., electric ground). Thus, the clock signal at the drains of transistors 528, 530 may be in the VDDA domain (e.g., transition between zero volts and VDDA, as shown in graph 537).

Similarly, the output of inverter 538 may be coupled to an input of another inverter 592 including transistors 532, 534. The gates of transistors 532, 534 may be coupled to an output of inverter 538, and drains of transistors 532, 534 may be coupled to a first terminal of a capacitive element 510 at node 568. As shown, the source of transistor 532 is coupled to the VDDA rail, and the source of transistor 534 is coupled to a reference potential node (e.g., electric ground). Thus, the clock signal at the drains of transistors 532, 534 may be in the VDDA domain (e.g., transition between zero volts and VDDA, as shown in graph 539).

Second terminals of capacitive elements 508, 510 may be coupled to respective nodes 574, 570 and to cross-coupled transistors 504, 506. Capacitive elements 508, 510 may be identical. In addition, transistors 504, 506 may be identical. Therefore, with the capacitive elements 508, 510 being identical and the transistors 504, 506 being identical, the clock signals shown in graphs 544, 546 are symmetric but with opposite polarities. For example, the source of transistor 504 may be coupled to the second terminal of capacitive element 508 and a gate of transistor 506. The source of transistor 506 may be coupled to node 570 and a gate of transistor 504. The drains of transistors 504, 506 may be coupled to the VDDA rail, as shown. When the CLK signal at the input of inverter 538 is logic low (e.g., at zero volts), the voltage at node 568 is at zero volts. Moreover, transistor 506 may be turned on, providing VDDA to node 570 and charging the capacitive element 510 to VDDA. When the CLK signal transitions to logic high, the voltage at node 568 transitions to VDDA which combines with the voltage (VDDA) across the capacitive element 510 to generate a voltage that is twice VDDA (e.g., which may be about equal to VDDB) at the node 570. Thus, the signal at node 570 transitions between VDDA and VDDB (e.g., twice VDDA) as shown in graph 546. Thus, the clock generation circuit 500 effectively performs pulse shaping to convert the pulse shape shown in graph 546 into the pulse shape shown in graph 540.

Similarly, when the CLKB signal at the input of inverter 536 is logic low (e.g., at zero volts), the voltage at node 572 is at zero volts. Moreover, transistor 504 may be turned on, providing VDDA to node 574 and charging the capacitive element 508 to VDDA. When the CLKB signal transitions to logic high, the voltage at node 572 transitions to VDDA which combines with the voltage (VDDA) across the capacitive element 508 to generate a voltage that is twice VDDA (e.g., which may be about equal to VDDB) at the node 574. Thus, the signal at node 574 transitions between VDDA and VDDB (e.g., twice VDDA) as shown in graph 544. The signal at node 574 may be complementary to the signal at node 570.

The clock generation circuit 500 may include an inverter 560 and an inverter 562 (e.g., collectively corresponding to the inverter circuitry 404 of FIG. 4). The inverter 560 may include a PMOS transistor 520 with a source coupled to the VDDB rail and a drain coupled to a source of a PMOS cascode transistor 522. A drain of transistor 522 may be coupled to an output 564 of the inverter 560, forming a first output of the clock generation circuit 500. The inverter 560 may also include an NMOS transistor 526 with a source coupled to the reference potential node and a drain coupled to a source of an NMOS cascode transistor 524. A drain of transistor 524 may be coupled to the output 564. As described, the clock signal at the output 564 may be used to drive a gate of a PMOS transistor 550 of a load, such as a mixer.

Similarly, the inverter 562 may include a PMOS transistor 512 with a source coupled to the VDDB rail and a drain coupled to a source of a PMOS cascode transistor 514. A drain of transistor 514 may be coupled to an output 566 of inverter 562, forming a second output of the clock generation circuit 500. The inverter 562 may also include an NMOS transistor 518 with a source coupled to the reference potential node and a drain coupled to a source of an NMOS cascode transistor 516. A drain of transistor 516 may be coupled to the output 566. The cascode transistors 514, 518, 522, 524 may be biased using a bias voltage (Vbias) at a bias voltage node. In some aspects, the cascode transistors may be included, optionally, to increase the headroom of the associated inverter, as described in more detail herein. The clock signal at the output 566 may be used to drive an NMOS transistor 548 of a load, such as a mixer.

As shown, the gate of transistor 520 may be coupled to node 570, and the gate of transistor 526 may be coupled to node 568. When the signal at node 570 is at VDDA and the signal at node 568 is at zero volts, transistor 520 is turned on, and transistor 526 is turned off, providing VDDB to the output 564. When the signal at node 570 is at VDDB and the signal at node 568 is at VDDA, transistor 520 is turned off, and transistor 526 is turned on, electrically coupling the reference potential node to the output 564. Thus, as shown in graph 540, the clock signal at output 564 is a clock signal transitioning

### Between Zero Volts and Vddb.

Transistors 522 and 524 may be biased via respective bias voltages Vbias1 and Vbias2. The transistor 522 may operate as a cascode device that protects transistor 520 from being exposed to the entire VDDB potential drop when the signal node 564 is logic low (e.g., at zero volts). Vbias1 facilitates balancing the voltage drop across the transistor 522. Similarly, 524 operates as a cascode device that protects transistor 526 from being exposed to the entire VDDB potential drop when the signal at node 564 is logic high (e.g., at VDDB). Vbias2 facilitates balancing the voltage drop across the transistor 524.

Similarly, the gate of transistor 512 may be coupled to node 574, and the gate of transistor 518 may be coupled to node 572. When the signal at node 574 is at VDDA and the signal at node 572 is at zero volts, transistor 512 is turned on, and transistor 518 is turned off, providing VDDB to the output 566. When the signal at node 574 is at VDDB and the signal at node 572 is at VDDA, transistor 512 is turned off, and transistor 518 is turned on, electrically coupling the reference potential node to the output 566. Thus, as shown in graph 542, the output signal at output 566 is a clock signal transitioning between zero volts and VDDB and is complementary to the clock signal at output 564. Thus, the clock generation circuit 500 effectively performs pulse shaping to convert the pulse shape shown in graph 544 into the pulse shape shown in graph 542.

Transistors 514 and 516 may be biased via bias voltages Vbias3 and Vbias4. Transistor 514 may operate as a cascode device that protects transistor 512 from being exposed to the entire VDDB potential drop when the signal at node 566 is logic low (e.g., at zero volts). Vbias3 facilitates balancing the voltage drop across the transistor 514. Similarly, transistor 516 operates as a cascode device that protects transistor 518 from being exposed to the entire VDDB potential drop when the signal at node 566 is logic high (e.g., at VDDB). Vbias4 facilitates balancing the voltage drop across the transistor 516.

The symmetric architecture of the clock generation circuit 500 generates complementary clock signals that can be used to drive NMOS and PMOS transistors 550, 548. For example, the clock signal at output 564 may be used to drive the NMOS transistor 550, and the clock signal at output 566 may be used to drive the PMOS transistor 548. In some aspects, the clock signal may be a local oscillator (LO) signal that is level-shifted using the clock generation circuit 500 to drive NMOS and PMOS transistors of a mixer such as the mixer 312 or mixer 324 of FIG. 3.

The clock generation circuit 500 uses two supply voltages VDDA and VDDB. Some aspects of the present disclosure are directed towards a single-supply clock generation circuit, facilitating a package-to-silicon area ratio that is more scalable with technology by reducing the number of pins for an integrated circuit (IC) and reducing parasitics with respect to the IC interfaces used to interface external circuitry. Providing multiple supply voltages to drive a clock tree of an IC increases the probability that the supply voltages are contaminated with spur signals. Some implementations with dual supplies are designed to use supply voltages within a certain threshold voltage from each other (e.g., hundreds of millivolts) so that an alternating-current (AC)-coupled self-biased buffer can interface the different supply voltage domains, placing restrictions on supply voltage levels and associated power savings.

Certain aspects of the present disclosure are directed towards clock generation circuitry that interfaces different clock domains in a manner that allows a higher voltage difference between the clock domains (e.g., where the logic high voltage of the clock signals of the different domains differ by a factor of two or more). Certain aspects provide a single-supply clock generation circuit with clock amplitude boosting to support the different clock domains.

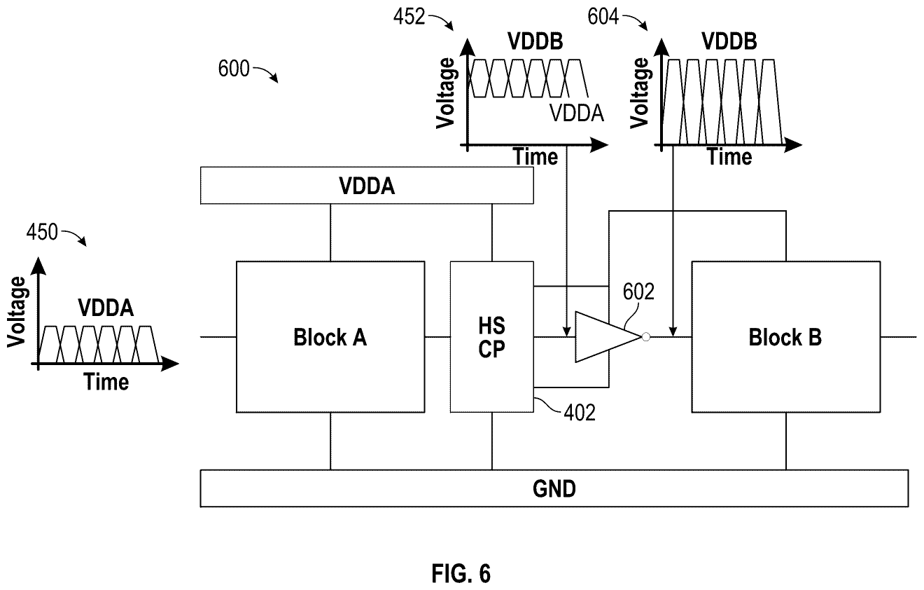

FIG. 6 is a block diagram of circuitry including a clock generation circuit 600 using a single supply voltage to interface different clock domains, in accordance with certain aspects of the present disclosure. As shown, the CP 402 may be powered using VDDA and may be coupled to inverter circuitry 602 that is powered by signals generated via the CP 402. The inverter circuitry 602 generates a clock signal for circuit block B without using a separate supply voltage VDDB. The CP 402 and inverter circuitry 602 level-shift the clock signal for the VDDA domain (e.g., with a logic high voltage of VDDA as shown in graph 450) to generate a clock signal for the VDDB domain (e.g., with a logic high voltage of VDDB as shown in graph 604). VDDB may be greater than VDDA by any suitable factor using, for example, a series of charge pumps and inverters as described in more detail herein.

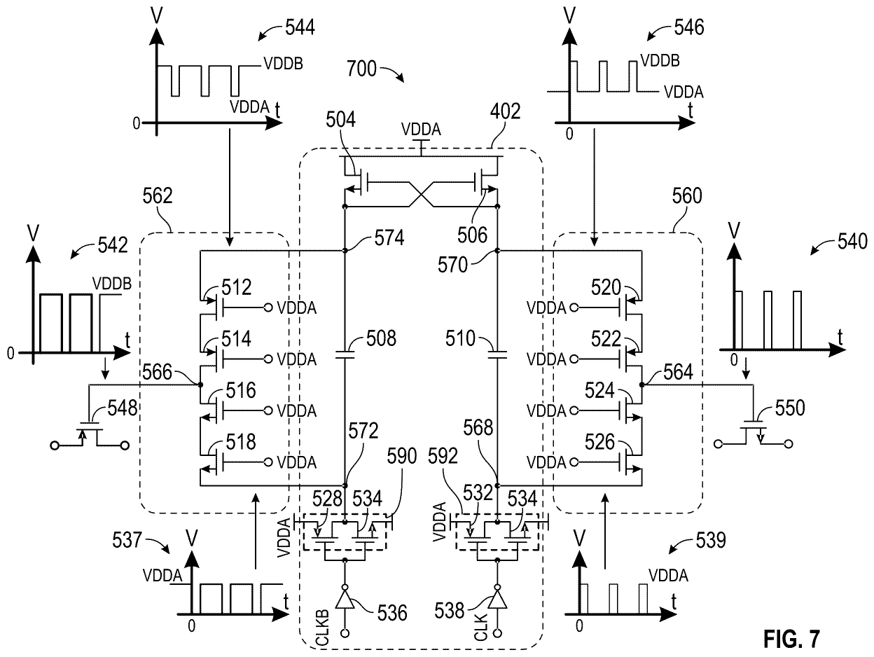

FIG. 7 illustrates a clock generation circuit 700 using a single supply voltage to interface different clock domains, in accordance with certain aspects of the present disclosure. As shown, instead of nodes 568, 570 being used to drive the gates of respective transistors 526, 520 as in the clock generation circuit 500, transistors 520, 522, 524, 526 may be biased using VDDA. The source of transistor 520 may be coupled to node 570, and the source of transistor 526 may be coupled to node 568. Thus, when the voltage at node 568 is at VDDA and the voltage at node 570 is at VDDB, the gate-to-source voltage of transistor 526 may be zero turning off transistor 526, and the source-to-gate voltage of transistor 520 may be equal to VDDB minus VDDA (e.g., equal to VDDA since VDDB is two times VDDA) turning on transistor 520. Therefore, the voltage at the output 564 may be equal to VDDB (e.g., the voltage at node 570). When the voltage at node 568 is at zero volts and the voltage at node 570 is at VDDA, the gate-to-source voltage of transistor 526 may be VDDA turning on transistor 526, and the source-to-gate voltage of transistor 520 may be zero volts turning off transistor 520. Therefore, the voltage at the output 564 may be equal to zero volts (e.g., the voltage at node 568). Therefore, the clock signal at the output 564 transitions between zero volts and VDDB.

Similarly, instead of nodes 572, 574 being used to drive the gates of respective transistors 518, 512 as in the clock generation circuit 500, transistors 512, 514, 516, 518 may be biased using VDDA. The source of transistor 512 may be coupled to node 574, and the source of transistor 518 may be coupled to node 572. Thus, when the voltage at node 572 is at VDDA and the voltage at node 574 is at VDDB, the gate-to-source voltage of transistor 518 may be zero turning off transistor 518, and the source-to-gate voltage of transistor 512 may be equal to VDDB minus VDDA (e.g., equal to VDDA since VDDB is two times VDDA) turning on transistor 512. Therefore, the voltage at the output 566 may be equal to VDDB (e.g., the voltage at node 574). When the voltage at node 572 is at zero volts and the voltage at node 574 is at VDDA, the gate-to-source voltage of transistor 518 may be VDDA turning on transistor 518, and the source-to-gate voltage of transistor 512 may be zero volts turning off transistor 512. Therefore, the voltage at the output 566 may be equal to zero volts (e.g., the voltage at node 572). Therefore, the clock signal at the output 566 transitions between zero volts and VDDB and is complementary to the clock signal at output 564. The clock generation circuit 700 effectively performs pulse shaping to convert the pulse shape shown in graph 544 into the pulse shape shown in graph 542, and convert the pulse shape shown in graph 546 into the pulse shape shown in graph 540. The bias voltages Vbias1 and Vbias2 may both be set to VDDA, but any suitable bias voltages may be used.

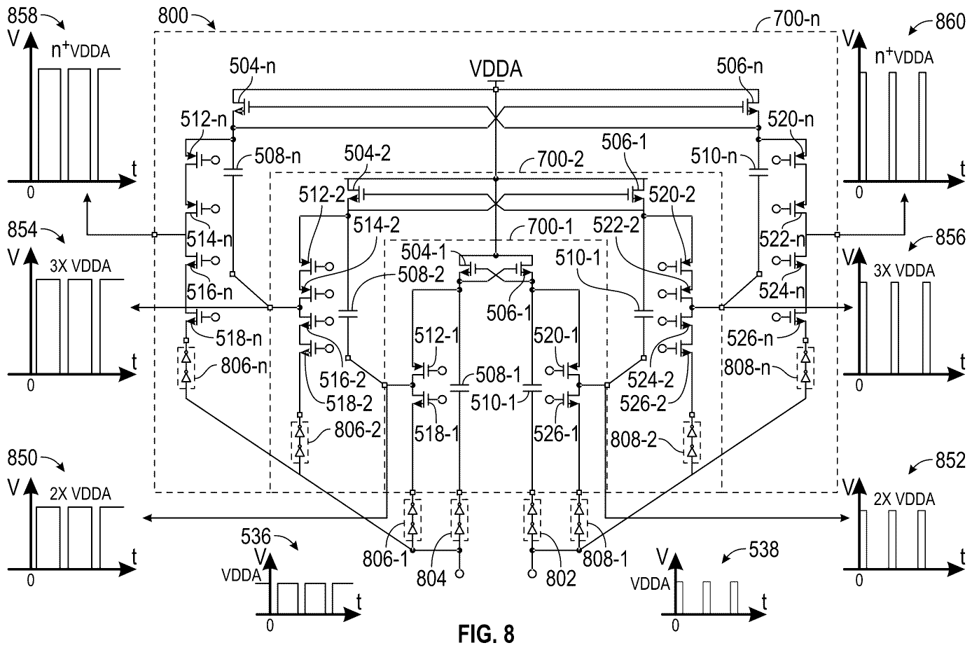

FIG. 8 illustrates an example sequential clock generation circuit 800, in accordance with certain aspects of the present disclosure. In some aspects, multiple clock generation circuits may be used to generate clock signals with higher logic high voltages. For example, the sequential clock generation circuit 800 may include a series of clock generation circuits 700-1, 700-2, to 700-n (n being a positive integer), where an output clock signal from one clock generation circuit is provided as input to a subsequent clock generation circuit to generate boosted clock signals. Each of the clock generation circuits 700-1, 700-2, to 700-n may correspond to the clock generation circuit 700 of FIG. 7. Each of the clock generation circuits 700-1, 700-2, to 700-n may include a CP implemented via respective capacitive elements 508-1 to 508-n (e.g., corresponding to capacitive element 508 of FIG. 7), respective capacitive elements 510-1 to 510-n (e.g., corresponding to capacitive element 510 of FIG. 7), and respective cross-coupled transistors 504-1 to 504-n and 506-1 to 506-n (e.g., corresponding to cross-coupled transistors 504, 506 of FIG. 7). Each of the clock generation circuits 700-1, 700-2, to 700-n also includes inverters implemented with transistors 512-1 to 512-n, 518-1 to 518-n, 520-1 to 520-n, and 526-1 to 526-n (e.g., corresponding to transistors 512, 518, 520, and 526 of FIG. 7). The inverters of the clock generation circuit 700-1 may be implemented without cascode transistors as the voltage of the clock signal may be low enough for the breakdown voltage of transistors 512-1, 518-1, 520-1, and 526-1 to withstand. However, the inverters of the clock generation circuits 700-2 to 700-n may be implemented with respective cascode transistors 514-2 to 514-n, 516-2 to 516-n, 522-2 to 522-n, and 524-2 to 524-n (e.g., corresponding to cascode transistors 514, 516, 522, and 524 of FIG. 7) to increase the headroom associated with the inverter (e.g., increase the overall breakdown voltage between each terminal of the charge pump capacitive element and the output of the inverter).

A series of inverters 802 (e.g., corresponding to inverters 538, 592 of FIG. 7) and a series of inverters 804 (e.g., corresponding to inverters 536, 590 of FIG. 7) may be used to provide clock signals to respective charge pump capacitive elements 510-1, 508-1 (e.g., corresponding to capacitive elements 510, 508 of FIG. 7) for the clock generation circuit 700-1. A series of inverters 806-1 and 808-1 may be used to provide clock signals to respective sources of transistors 518-1 and 526-1 of the clock generation circuit 700-1. In some cases, instead of using inverters 806-1 and 808-1, the output of the inverter 804 may be coupled to the source of transistors 518-1, and the output of the inverter 802 may be coupled to the source of transistors 526-1. Similarly, the series of inverters 806-2 to 806-n may be used to buffer the CLKB signal and provide the buffered CLKB signal to respective sources of transistors 518-2 to 518-n, and the series of inverters 808-2 to 808-n may be used to buffer the CLK signal and provide the buffered CLK signal to respective sources of transistors 526-2 to 526-n.

As shown, the clock signals at the outputs of the clock generation circuit 700-1 may have a logic high voltage that is two times VDDA as shown in graphs 850, 852. The clock signals at the outputs of the clock generation circuit 700-1 are provided to clock generation circuit 700-2 to generate the clock signals shown in graphs 854, 856 having a logic high voltage of three times VDDA. Any suitable number of clock generation circuits may be used to continually increase the logic high voltage of the clock signals. For example, the clock signals at the outputs of clock generation circuit 700-n may have a logic high voltage of n times VDDA, as shown in graphs 858, 860.

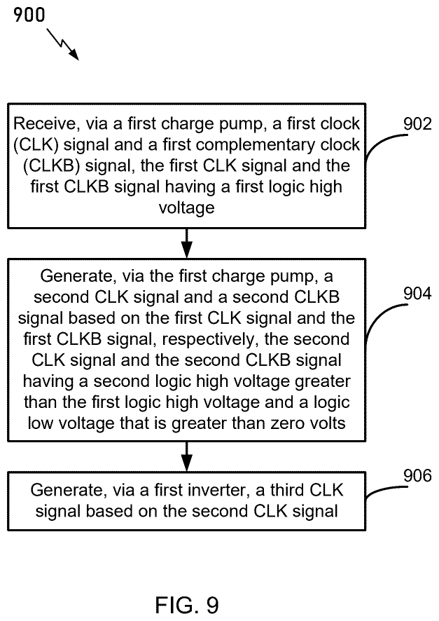

FIG. 9 is a flow diagram illustrating example operations 900 for clock generation, in accordance with certain aspects of the present disclosure. The operations 900 may be performed, for example, by clock generation circuitry such as the clock generation circuit 500, the clock generation circuit 700, or the sequential clock generation circuit 800.

At block 902, the clock generation circuitry receives, via a first charge pump (e.g., CP 402 of FIG. 4 or FIG. 7), a first clock (CLK) signal and a first complementary clock (CLKB) signal. The first CLK signal and the first CLKB signal may have a first logic high voltage (e.g., VDDA).

At block 904, the clock generation circuitry generates, via the first charge pump, a second CLK signal and a second CLKB signal based on the first CLK signal and the first CLKB signal, respectively. The second CLK signal and the second CLKB signal may have a second logic high voltage (e.g., VDDB or two times VDDA) greater than the first logic high voltage and a logic low voltage (e.g., VDDA) that is greater than zero volts.

At block 906, the clock generation circuitry may generate, via a first inverter (e.g., inverter 560 of FIG. 4 or FIG. 7), a third CLK signal based on the second CLK signal. At block 908, the clock generation circuitry may generate, via a second inverter (e.g., inverter 562 of FIG. 4 or FIG. 7), a third CLKB signal based on the second CLKB signal, the third CLK signal and the third CLKB signal comprising the second logic high voltage and a logic low voltage that is zero volts. The second logic high voltage may be twice the first logic high voltage.

In some aspects, the clock generation circuitry may generate the first CLK signal via a first set of inverters (e.g., inverters 538, 592) and generate the first CLKB signal via a second set of inverters (e.g., inverters 536, 590). The clock generation circuitry may drive a gate of a first transistor (e.g., transistor 526) of the first inverter via the first CLK signal and a gate of a second transistor (e.g., transistor 520) of the first inverter via the second CLK signal. The clock generation circuitry may drive a gate of a third transistor (e.g., transistor 518) of the second inverter via the first CLKB signal and a gate of a fourth transistor (e.g., transistor 512) of the second inverter via the second CLKB signal.

In some aspects, generating the third CLK signal may include: providing, via a first transistor (e.g., transistor 526) of the first inverter, the first CLK signal to an output of the first inverter when the first CLK signal is logic low; and providing, via a second transistor (e.g., transistor 520) of the first inverter, the second CLK signal to the output of the first inverter when the first CLK signal is logic high. Generating the third CLKB signal may include: providing, via a third transistor (e.g., transistor 518) of the second inverter, the first CLKB signal to an output of the second inverter when the first CLKB signal is logic low; and providing, via a fourth transistor (e.g., transistor 512) of the second inverter, the second CLKB signal to the output of the second inverter when the first CLKB signal is logic high.

In some aspects, the clock generation circuitry may receive, via a second charge pump (e.g., charge pump of clock generation circuit 700-2 of FIG. 8 including capacitive elements 508-2, 510-2)), the third CLK signal and the third CLKB signal. The clock generation circuitry may generate, via the second charge pump, a fourth CLK signal and a fourth CLKB signal based on the third CLK signal and the third CLKB signal, respectively. The third CLK signal and the third CLKB signal may have a third logic high voltage (e.g., three times VDDA) greater than the second logic high voltage and a logic low voltage that is greater than zero volts. The clock generation circuitry may generate, via a third inverter (e.g., inverter of clock generation circuit 700-2 of FIG. 8 including transistors 520-2 and 526-2), a fifth CLK signal based on the fourth CLK signal. The clock generation circuitry may generate, via a fourth inverter (e.g., inverter of clock generation circuit 700-2 including transistors 512-2 and 518-2), a fifth CLKB signal based on the fourth CLKB signal. The fifth CLK signal and the fifth CLKB signal may have the third logic high voltage and a logic low voltage that is zero volts.

### EXAMPLE ASPECTS

Aspect 1: An apparatus for clock generation, comprising: a first charge pump coupled to a first voltage rail and including a first capacitive element and a second capacitive element, a first terminal of the first capacitive element being coupled to a clock (CLK) node and a first terminal of the second capacitive element being coupled to a complementary clock (CLKB) node; a first inverter including a first transistor and a second transistor with a gate or source coupled to a second terminal of the first capacitive element, drains of the first transistor and the second transistor being coupled to an output of the first inverter; and a second inverter including a third transistor and a fourth transistor with a gate or source coupled to a second terminal of the second capacitive element, drains of the third transistor and the fourth transistor being coupled to an output of the second inverter.
Aspect 2: The apparatus of Aspect 1, wherein: a gate or source of the first transistor is coupled to the first terminal of the first capacitive element; and a gate or source of the third transistor is coupled to the first terminal of the second capacitive element.
Aspect 3: The apparatus of Aspect 1 or 2, wherein the first charge pump further comprises: a fifth transistor with a source coupled to the second terminal of the first capacitive element and a drain coupled to the first voltage rail; and a sixth transistor with a source coupled to the second terminal of the second capacitive element and to a gate of the fifth transistor and a drain coupled to the first voltage rail, wherein the source of the fifth transistor is coupled to a gate of the sixth transistor.
Aspect 4: The apparatus according to any of Aspects 1-3, wherein: the first inverter further includes a first cascode transistor with a source coupled to the drain of the first transistor and a second cascode transistor with a source coupled to the drain of the second transistor, drains of the first cascode transistor and the second cascode transistor being coupled to the output of the first inverter; and the second inverter further includes a third cascode transistor with a source coupled to the drain of the third transistor and a fourth cascode transistor with a source coupled to the drain of the fourth transistor, drains of the third cascode transistor and the fourth cascode transistor being coupled to the output of the second inverter.
Aspect 5: The apparatus according to any of Aspects 1-4, wherein: the first terminal of the first capacitive element is coupled to the gate of the first transistor; the second terminal of the first capacitive element is coupled to the gate of the second transistor; the first terminal of the second capacitive element is coupled to the gate of the third transistor; the second terminal of the second capacitive element is coupled to the gate of the fourth transistor; and sources of the second transistor and the fourth transistor are coupled to a second voltage rail different than the first voltage rail.
Aspect 6: The apparatus according to any of Aspects 1-5, wherein: the first terminal of the first capacitive element is coupled to the source of the first transistor; the second terminal of the first capacitive element is coupled to the source of the second transistor; the first terminal of the second capacitive element is coupled to the source of the third transistor; and the second terminal of the second capacitive element is coupled to the source of the fourth transistor.
Aspect 7: The apparatus of Aspect 6, wherein the gate of each of the first transistor, the second transistor, the third transistor, and the fourth transistor are coupled to the first voltage rail.
Aspect 8: The apparatus according to any of Aspects 1-7, further comprising: a first set of inverters coupled between the CLK node and the first terminal of the first capacitive element; and a second set of inverters coupled between the CLKB node and the first terminal of the second capacitive element.
Aspect 9: The apparatus of Aspect 8, further comprising: third set of inverters coupled between the CLK node and a source of the first transistor; and a fourth set of inverters coupled between the CLKB node and a source of the third transistor.
Aspect 10: The apparatus according to any of Aspects 1-9, wherein: the first charge pump is configured to: receive a first CLK signal and a first CLKB signal, the first CLK signal and the first CLKB signal being configured to have a first logic high voltage; and generate a second CLK signal and a second CLKB signal based on the first CLK signal and the first CLKB signal, respectively, the second CLK signal and the second CLKB signal being configured to have a second logic high voltage greater than the first logic high voltage; the first inverter is configured to generate a third CLK signal based on the second CLK signal; and the second inverter is configured to generate a third CLKB signal based on the second CLKB signal, the third CLK signal and the third CLKB signal being configured to have the second logic high voltage.
Aspect 11: The apparatus of Aspect 10, wherein the second logic high voltage is twice the first logic high voltage.
Aspect 12: The apparatus of Aspect 11, further comprising: a first set of inverters configured to generate the first CLK signal; and a second set of inverters configured to generate the first CLKB signal.
Aspect 13: The apparatus according to any of Aspects 1-12, further comprising: a second charge pump coupled to the first voltage rail and including a third capacitive element and a fourth capacitive element, a first terminal of the third capacitive element being coupled to the output of the first inverter and a first terminal of the fourth capacitive element being coupled to the output of the second inverter; a third inverter including a fifth transistor with a source coupled to the first terminal of the first capacitive element, and a sixth transistor with a source coupled to a second terminal of the third capacitive element, drains of the fifth transistor and the sixth transistor being coupled to an output of the third inverter; and a fourth inverter including a seventh transistor with a source coupled to the first terminal of the fourth capacitive element, and an eighth transistor with a source coupled to a second terminal of the fourth capacitive element, drains of the seventh transistor and the eighth transistor being coupled to an output of the fourth inverter.
Aspect 14: A method for clock generation, comprising: receiving, via a first charge pump, a first clock (CLK) signal and a first complementary clock (CLKB) signal, the first CLK signal and the first CLKB signal having a first logic high voltage; generating, via the first charge pump, a second CLK signal and a second CLKB signal based on the first CLK signal and the first CLKB signal, respectively, the second CLK signal and the second CLKB signal having a second logic high voltage greater than the first logic high voltage; generating, via a first inverter, a third CLK signal based on the second CLK signal; and generating, via a second inverter, a third CLKB signal based on the second CLKB signal, the third CLK signal and the third CLKB signal comprising the second logic high voltage.
Aspect 15: The method of Aspect 14, wherein the second logic high voltage is twice the first logic high voltage.
Aspect 16: The method of Aspect 14 or 15, further comprising: generating the first CLK signal via a first set of inverters; and generating the first CLKB signal via a second set of inverters.
Aspect 17: The method according to any of Aspects 14-16, further comprising: driving a gate of a first transistor of the first inverter via the first CLK signal and a gate of a second transistor of the first inverter via the second CLK signal; and driving a gate of a third transistor of the second inverter via the first CLKB signal and a gate of a fourth transistor of the second inverter via the second CLKB signal.
Aspect 18: The method according to any of Aspects 14-17, wherein generating the third CLK signal comprises: providing, via a first transistor of the first inverter, the first CLK signal to an output of the first inverter when the first CLK signal is logic low; and providing, via a second transistor of the first inverter, the second CLK signal to the output of the first inverter when the first CLK signal is logic high.
Aspect 19: The method of Aspect 18, wherein generating the third CLKB signal comprises: providing, via a third transistor of the second inverter, the first CLKB signal to an output of the second inverter when the first CLKB signal is logic low; and providing, via a fourth transistor of the second inverter, the second CLKB signal to the output of the second inverter when the first CLKB signal is logic high.
Aspect 20: The method according to any of Aspects 14-19, further comprising: receiving, via a second charge pump, the third CLK signal and the third CLKB signal; generating, via the second charge pump, a fourth CLK signal and a fourth CLKB signal based on the third CLK signal and the third CLKB signal, respectively, the third CLK signal and the third CLKB signal having a third logic high voltage greater than the second logic high voltage; generating, via a third inverter, a fifth CLK signal based on the fourth CLK signal; and generating, via a fourth inverter, a fifth CLKB signal based on the fourth CLKB signal, the fifth CLK signal and the fifth CLKB signal comprising the third logic high voltage.
Aspect 21: An apparatus for clock generation, comprising: a first charge pump coupled to a first voltage rail and including a first capacitive element and a second capacitive element, a first terminal of the first capacitive element being coupled to a clock (CLK) node and a first terminal of the second capacitive element being coupled to a complementary clock (CLKB) node; a first inverter including a first transistor with a source coupled to the first terminal of the first capacitive element and a second transistor with a source coupled to a second terminal of the first capacitive element, drains of the first transistor and the second transistor being coupled to an output of the first inverter; and a second inverter including a third transistor with a source coupled to the first terminal of the second capacitive element and a fourth transistor with a source coupled to a second terminal of the second capacitive element, drains of the third transistor and the fourth transistor being coupled to an output of the second inverter.
Aspect 22: The apparatus of Aspect 21, wherein the first charge pump further comprises: a fifth transistor with a source coupled to the second terminal of the first capacitive element and a drain coupled to the first voltage rail; and a sixth transistor with a source coupled to the second terminal of the second capacitive element and to a gate of the fifth transistor and a drain coupled to the first voltage rail, wherein the source of the fifth transistor is coupled to a gate of the sixth transistor.
Aspect 23: The apparatus of Aspect 21 or 22, wherein: the first inverter further includes a first cascode transistor with a source coupled to the drain of the first transistor and a second cascode transistor with a source coupled to the drain of the second transistor, drains of the first cascode transistor and the second cascode transistor being coupled to the output of the first inverter; and the second inverter further includes a third cascode transistor with a source coupled to the drain of the third transistor and a fourth cascode transistor with a source coupled to the drain of the fourth transistor, drains of the third cascode transistor and the fourth cascode transistor being coupled to the output of the second inverter.
Aspect 24: The apparatus according to any of Aspects 21-23, further comprising: a first set of inverters coupled between the CLK node and the first terminal of the first capacitive element; and a second set of inverters coupled between the CLKB node and the first terminal of the second capacitive element.
Aspect 25: The apparatus of Aspect 24, further comprising: a third set of inverters coupled between the CLK node and a source of the first transistor; and a fourth set of inverters coupled between the CLKB node and a source of the third transistor.
Aspect 26: The apparatus according to any of Aspects 21-25, further comprising: a second charge pump coupled to the first voltage rail and including a third capacitive element and a fourth capacitive element, a first terminal of the third capacitive element being coupled to the output of the first inverter and a first terminal of the fourth capacitive element being coupled to the output of the second inverter; a third inverter including a fifth transistor with a source coupled to the first terminal of the first capacitive element, and a sixth transistor with a source coupled to a second terminal of the third capacitive element, drains of the fifth transistor and the sixth transistor being coupled to an output of the third inverter; and a fourth inverter including a seventh transistor with a source coupled to the first terminal of the fourth capacitive element, and an eighth transistor with a source coupled to a second terminal of the fourth capacitive element, drains of the seventh transistor and the eighth transistor being coupled to an output of the fourth inverter.

### ADDITIONAL CONSIDERATIONS

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. An apparatus for clock generation, comprising:
a first charge pump coupled to a first voltage rail and including a first capacitive element and a second capacitive element, a first terminal of the first capacitive element being coupled to a clock (CLK) node and a first terminal of the second capacitive element being coupled to a complementary clock (CLKB) node;
a first inverter including a first transistor and a second transistor with a gate or source coupled to a second terminal of the first capacitive element, drains of the first transistor and the second transistor being coupled to an output of the first inverter; and
a second inverter including a third transistor and a fourth transistor with a gate or source coupled to a second terminal of the second capacitive element, drains of the third transistor and the fourth transistor being coupled to an output of the second inverter.

2. The apparatus of claim 1, wherein:
a gate or source of the first transistor is coupled to the first terminal of the first capacitive element; and
a gate or source of the third transistor is coupled to the first terminal of the second capacitive element.

3. The apparatus of claim 1, wherein the first charge pump further comprises:
a fifth transistor with a source coupled to the second terminal of the first capacitive element and a drain coupled to the first voltage rail; and
a sixth transistor with a source coupled to the second terminal of the second capacitive element and to a gate of the fifth transistor and a drain coupled to the first voltage rail, wherein the source of the fifth transistor is coupled to a gate of the sixth transistor.

4. The apparatus of claim 1, wherein:
the first inverter further includes a first cascode transistor with a source coupled to the drain of the first transistor and a second cascode transistor with a source coupled to the drain of the second transistor, drains of the first cascode transistor and the second cascode transistor being coupled to the output of the first inverter; and
the second inverter further includes a third cascode transistor with a source coupled to the drain of the third transistor and a fourth cascode transistor with a source coupled to the drain of the fourth transistor, drains of the third cascode transistor and the fourth cascode transistor being coupled to the output of the second inverter.

5. The apparatus of claim 1, wherein:
the first terminal of the first capacitive element is coupled to the gate of the first transistor;
the second terminal of the first capacitive element is coupled to the gate of the second transistor;
the first terminal of the second capacitive element is coupled to the gate of the third transistor;
the second terminal of the second capacitive element is coupled to the gate of the fourth transistor; and
sources of the second transistor and the fourth transistor are coupled to a second voltage rail different than the first voltage rail.

6. The apparatus of claim 1, wherein:
the first terminal of the first capacitive element is coupled to the source of the first transistor;
the second terminal of the first capacitive element is coupled to the source of the second transistor;
the first terminal of the second capacitive element is coupled to the source of the third transistor; and
the second terminal of the second capacitive element is coupled to the source of the fourth transistor.

7. The apparatus of claim 6, wherein the gate of each of the first transistor, the second transistor, the third transistor, and the fourth transistor are coupled to the first voltage rail.

8. The apparatus of claim 1, further comprising:
a first set of inverters coupled between the CLK node and the first terminal of the first capacitive element; and
a second set of inverters coupled between the CLKB node and the first terminal of the second capacitive element.

9. The apparatus of claim 8, further comprising:
a third set of inverters coupled between the CLK node and a source of the first transistor; and
a fourth set of inverters coupled between the CLKB node and a source of the third transistor.

10. The apparatus of claim 1, wherein:
the first charge pump is configured to:
receive a first CLK signal and a first CLKB signal, the first CLK signal and the first CLKB signal being configured to have a first logic high voltage; and
generate a second CLK signal and a second CLKB signal based on the first CLK signal and the first CLKB signal, respectively, the second CLK signal and the second CLKB signal being configured to have a second logic high voltage greater than the first logic high voltage;
the first inverter is configured to generate a third CLK signal based on the second CLK signal; and
the second inverter is configured to generate a third CLKB signal based on the second CLKB signal, the third CLK signal and the third CLKB signal being configured to have the second logic high voltage.

11. The apparatus of claim 10, wherein the second logic high voltage is twice the first logic high voltage.

12. The apparatus of claim 11, further comprising:
a first set of inverters configured to generate the first CLK signal; and
a second set of inverters configured to generate the first CLKB signal.

13. The apparatus of claim 1, further comprising:
a second charge pump coupled to the first voltage rail and including a third capacitive element and a fourth capacitive element, a first terminal of the third capacitive element being coupled to the output of the first inverter and a first terminal of the fourth capacitive element being coupled to the output of the second inverter;
a third inverter including a fifth transistor with a source coupled to the first terminal of the first capacitive element, and a sixth transistor with a source coupled to a second terminal of the third capacitive element, drains of the fifth transistor and the sixth transistor being coupled to an output of the third inverter; and
a fourth inverter including a seventh transistor with a source coupled to the first terminal of the fourth capacitive element, and an eighth transistor with a source coupled to a second terminal of the fourth capacitive element, drains of the seventh transistor and the eighth transistor being coupled to an output of the fourth inverter.

14. A method for clock generation, comprising:
receiving, via a first charge pump, a first clock (CLK) signal and a first complementary clock (CLKB) signal, the first CLK signal and the first CLKB signal having a first logic high voltage;
generating, via the first charge pump, a second CLK signal and a second CLKB signal based on the first CLK signal and the first CLKB signal, respectively, the second CLK signal and the second CLKB signal having a second logic high voltage greater than the first logic high voltage;
generating, via a first inverter, a third CLK signal based on the second CLK signal; and
generating, via a second inverter, a third CLKB signal based on the second CLKB signal, the third CLK signal and the third CLKB signal comprising the second logic high voltage.

15. The method of claim 14, wherein the second logic high voltage is twice the first logic high voltage.

16. The method of claim 14, further comprising:
generating the first CLK signal via a first set of inverters; and
generating the first CLKB signal via a second set of inverters.

17. The method of claim 14, further comprising:
driving a gate of a first transistor of the first inverter via the first CLK signal and a gate of a second transistor of the first inverter via the second CLK signal; and
driving a gate of a third transistor of the second inverter via the first CLKB signal and a gate of a fourth transistor of the second inverter via the second CLKB signal.

18. An apparatus for clock generation, comprising:
a first charge pump coupled to a first voltage rail and including a first capacitive element and a second capacitive element, a first terminal of the first capacitive element being coupled to a clock (CLK) node and a first terminal of the second capacitive element being coupled to a complementary clock (CLKB) node;
a first inverter including a first transistor with a source coupled to the first terminal of the first capacitive element and a second transistor with a source coupled to a second terminal of the first capacitive element, drains of the first transistor and the second transistor being coupled to an output of the first inverter; and
a second inverter including a third transistor with a source coupled to the first terminal of the second capacitive element and a fourth transistor with a source coupled to a second terminal of the second capacitive element, drains of the third transistor and the fourth transistor being coupled to an output of the second inverter.

19. The apparatus of claim 18, wherein the first charge pump further comprises:
a fifth transistor with a source coupled to the second terminal of the first capacitive element and a drain coupled to the first voltage rail; and
a sixth transistor with a source coupled to the second terminal of the second capacitive element and to a gate of the fifth transistor and a drain coupled to the first voltage rail, wherein the source of the fifth transistor is coupled to a gate of the sixth transistor.

20. The apparatus of claim 18, further comprising:
a second charge pump coupled to the first voltage rail and including a third capacitive element and a fourth capacitive element, a first terminal of the third capacitive element being coupled to the output of the first inverter and a first terminal of the fourth capacitive element being coupled to the output of the second inverter;
a third inverter including a fifth transistor with a source coupled to the first terminal of the first capacitive element, and a sixth transistor with a source coupled to a second terminal of the third capacitive element, drains of the fifth transistor and the sixth transistor being coupled to an output of the third inverter; and
a fourth inverter including a seventh transistor with a source coupled to the first terminal of the fourth capacitive element, and an eighth transistor with a source coupled to a second terminal of the fourth capacitive element, drains of the seventh transistor and the eighth transistor being coupled to an output of the fourth inverter.
